(19) United States
(12) Patent Application Publication
(10) Pub. No.: US 2013/0037311 A1
(43) Pub. Date: Feb. 14, 2013

(54) FUNCTIONALIZATION OF THERMAL MANAGEMENT MATERIALS

(71) Applicants: NAN JIANG, Austin, TX (US); ZVI YANIV, Austin, TX (US)

(72) Inventors: NAN JIANG, Austin, TX (US); ZVI YANIV, Austin, TX (US)

(73) Assignee: APPLIED NANOTECH HOLDINGS, INC., Austin, TX (US)

(21) Appl. No.: 13/570,612

(22) Filed: Aug. 9, 2012

Related U.S. Application Data
(60) Provisional application No. 61/523,209, filed on Aug. 12, 2011.

(51) Int. Cl. H05K 1/03; B05D 3/06; B05D 3/10; C23C 28/00; B05D 5/12

(52) U.S. Cl. 174/255; 205/190; 427/97.1; 427/97.6; 427/97.4; 427/553

(57) ABSTRACT

A base material or composite material such as graphite, may be combined with another material, such as aluminum oxide or polyimide, to produce a new insulating thermal management material. The base material may be impregnated with another metal to create a composite base material.

This application claims priority to U.S. Provisional Application Ser. No. 61/523,209. which is hereby incorporated by reference herein.

### BACKGROUND AND SUMMARY

Thermal management materials with high thermal conductivity, high thermal diffusivity, machineability, and/or low coefficient of thermal expansion (“CTE”) at low cost are desirable. For many electronic applications, it would be beneficial if the material were not electrically conductive so that electronic components could be assembled directly onto the high thermal conductivity material. Typically, however, materials with high thermal conductivity are also electrically conductive. For example, carbon-based materials, such as graphite and graphene, typically have high thermal conductivity, but they are electrically conductive. It would he desirable to have a high thermal conductivity (e.g., approximately 250 W/m−K-450 W/m−K) material, such as a graphite-based material, that incorporated a dielectric material that was not electrically conductive. Ideally, the thickness of the dielectric material would be controllable, and the dielectric portions could be selectively patterned. This would enable applications requiring a low cost high thermal conductivity substrate, such as for LED lamps, photovoltaics, power electronics, etc.

Aspects of the invention disclosed herein combine a base material or composite, such as but not limited to graphite, with another layer. By combining a base material such as graphite with another subsequent material (e.g., aluminum or polyimide) a new insulating thermal management material is created.

The base material may be a number of different types of materials, including the use of graphite material, or the use of a porous graphite material that has been previously impregnated with a metal (e.g., using a high pressure and/or high temperature process) creating a composite base material.

Described herein are examples of using graphite as the base material and aluminum or polyimide as the second material, with the understanding that this concept can be extended to other material combinations.

### BRIEF DESCRIPTION OF THE DRAWINGS

FIG. 1 illustrates schematic diagrams of a process (as indicated by the arrows between the diagrams) to incorporate aluminum onto graphite,

FIG. 2 illustrates variations of thickness of aluminum (Al) and aluminum-oxide combinations using processes described herein.

FIG. 3 (FIGS. 3A-3D) shows digital photographs of anodized Al layers (e.g.,. insulating Al-oxide layer) on graphite.

FIG. 4 illustrates a fabrication process of conductive circuitry on a dielectric graphitic substrate.

FIG. 5 (FIGS. 5A-5B) shows digital photographs of conductive circuitry formed on polyimide-based—dielectric/graphite substrates (e.g., by a process described with respect to FIG. 4 and as described otherwise herein).

### DETAILED DESCRIPTION

Aluminum can be placed (deposited) onto graphite in a number of ways, such as, but not limited to: 1) lamination or gluing of aluminum foil onto graphite; 2) evaporation (e.g., using an electron beam, thermal, chemical, and/or other means to deposit aluminum onto the surface of the graphite); 3) sputtering (e.g., using electromagnetic energy to transfer aluminum onto the surface of the graphite); 4) bonding of foils (e.g., sheets of aluminum foils laminated, pressed, anodically bonded, or otherwise applied to the surface of the graphite); 5) coating aluminum pastes and inks on the surface (e.g., coating an aluminum ink or paste onto the surface of the graphite and then curing it at a high enough temperature to form a layer of aluminum on the surface of the graphite (this is an attractive alternative because it can be done relatively easily at a low cost); 6) molding and/or casting molten aluminum on the surface of the graphite and then cooling it (e.g., graphite may be placed into a mold and molten aluminum poured in, and under pressure and temperature, the aluminum is impregnated into the graphite (e.g., when the component part is cooled, a surface layer of aluminum remains in place as a “skin”); 7) dip coating (e.g., coating the graphite parts in molten aluminum (e.g., by dipping parts into a molten aluminum bath)).

The thickness of the aluminum may he controlled either during these processes to give a specific desired thickness, or accomplished during post-processing by chemical etching or physical removal, such as grinding, lapping, or polishing down the aluminum to a desired thickness. Any of these methods, as well as others, and combinations thereof, may be used; nevertheless, a layer of a metal (e.g., aluminum) is created on top of (over) the base material (e.g., graphite). The metal and/or metal alloy layer is not limited to aluminum and may he other metals, such as copper, nickel, gold, silver, tin, titanium, magnesium, zinc, niobium, tantalum, brass, solders, and/or other alloys of metals with other metals as well as with dopants. Herein, aluminum is disclosed as an example.

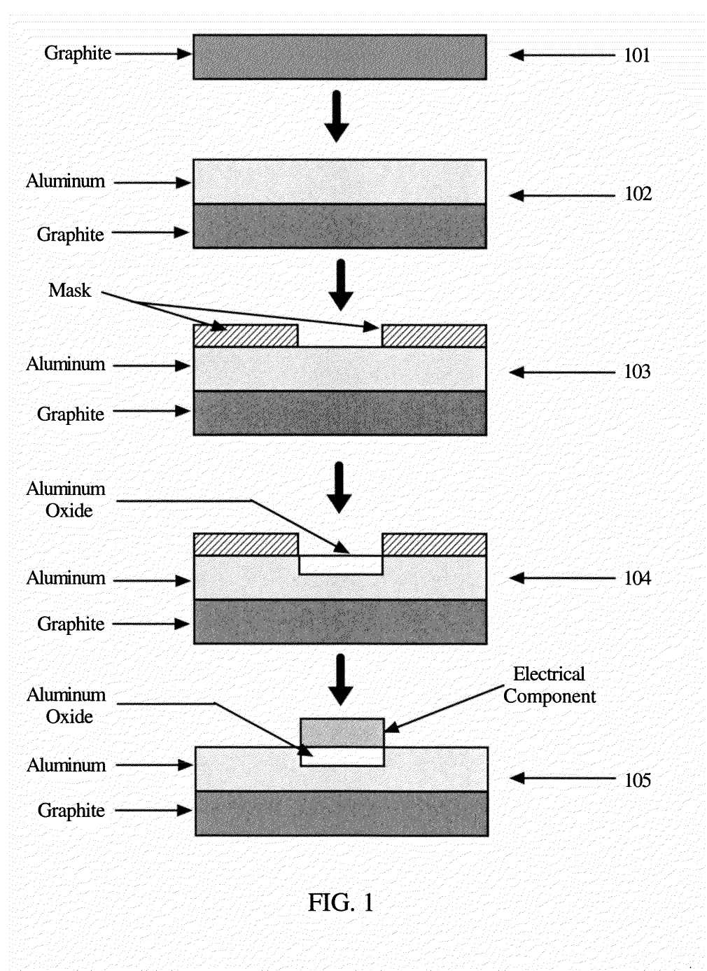

Referring to FIG. 1, in step 101 a substrate (e.g., graphite) is provided. After aluminum (or alternatively another metal) is placed (e.g., deposited) on the surface of the graphite in step 102, the surface of the aluminum may be oxidized, such as through an anodization process, which essentially increases the thickness of the natural oxide layer on the surface of metal parts through an electrolytic passivation process. Therefore, a result of aluminum anodization is an aluminum oxide layer, as shown in step 104. Anodizing the aluminum creates a non-conductive dielectric layer, which makes the material easier to integrate with electronic components (including conductive circuitry) that need a non-conductive surface. Furthermore, regions of the aluminum layer may be selectively oxidized by pre-masking the aluminum surface to obtain a patterned dielectric layer, such as illustrated in steps 103 and 104.

Various methods of anodization may be used, such as, but not limited to, chromic acid anodizing, sulfuric acid anodizing, organic acid anodizing, phosphoric acid anodizing, borate and tartrate baths, plasma electrolytic oxidation, and/or equivalent means. Other metals than aluminum, such as titanium, magnesium, zinc, niobium, and tantalum, may be utilized and anodized, but the usable metals are not limited to these.

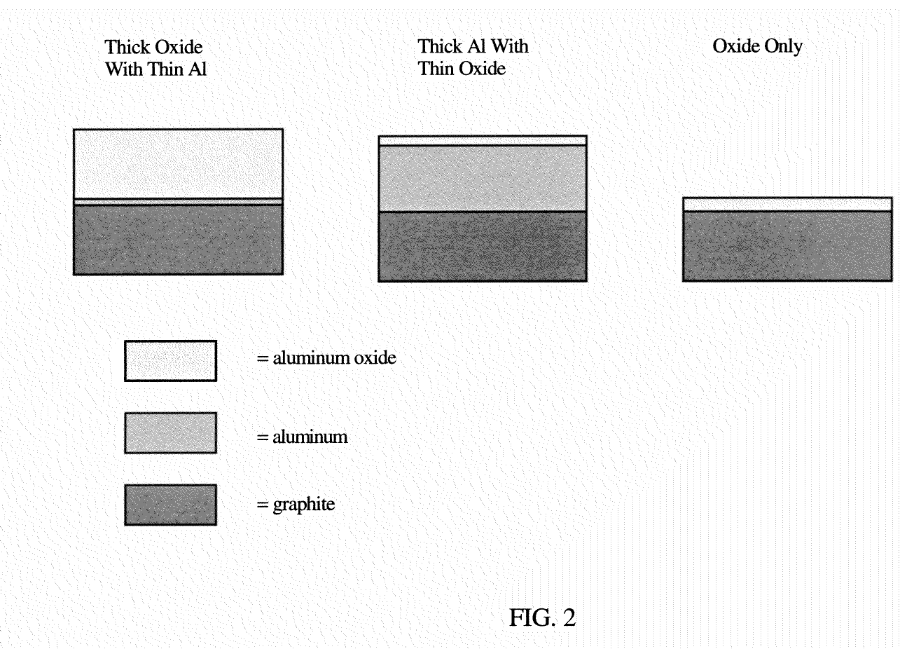

Referring to FIG. 2, the thickness of the anodized layer may he adjusted via the anodization process. The process can be varied so that the anodized layer consumes substantially all of the aluminum if that is desired, or it can he merely the top surface, as a function of what is desirable for the end application. FIG. 2 illustrates such resultant alternatives showing a thick oxide layer produced with a thin metal layer on the substrate (e.g., graphite), a thin oxide layer on a thicker metal layer, or only an oxide layer remaining on the substrate. The thicker the anodized layer, the less thermal conductivity the material will have, while a thinner layer provides better thermal conductivity at the cost of other material property benefits.

As previously mentioned, depending upon the requirements of a specific application for the resultant composite, a corresponding oxidation pattern may he designed by selectively masking the aluminum surface (see steps 103 and 104 in FIG. 1). The oxidized area(s) provide the electrical insulation as needed by electrical component(s) deposited or placed over the oxidized area(s), such as illustrated by the example in step 105 in FIG. 1, with the non-oxidized regions providing conduction and thermal dissipation paths.

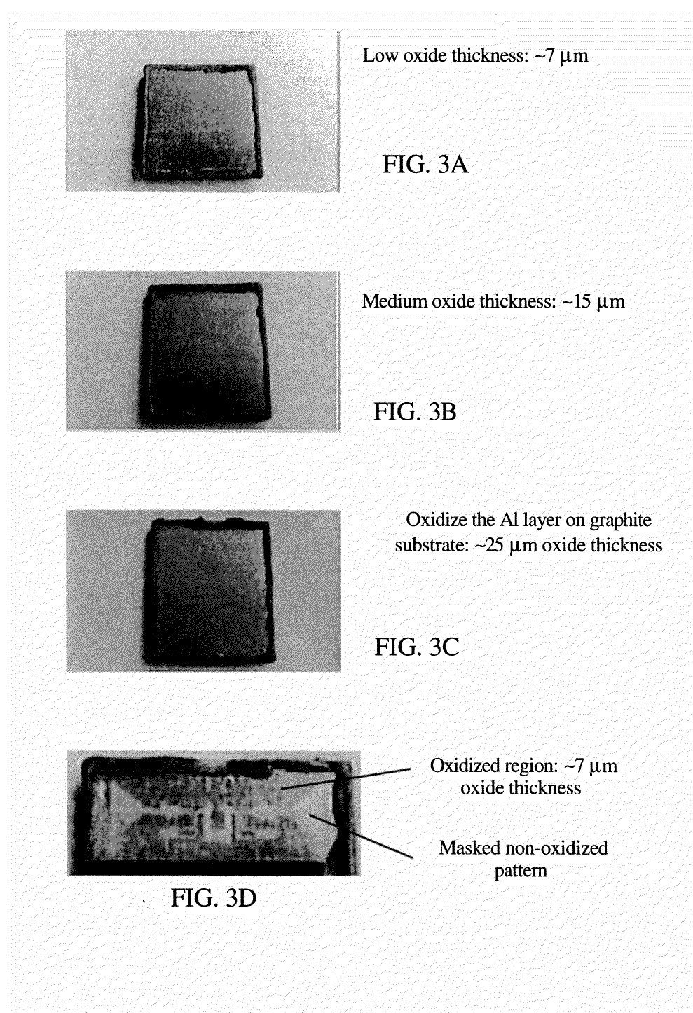

FIG. 3 shows samples with different oxidation thicknesses and selected oxidation patterns. FIGS. 3A-3D) of FIG. 3 show digital photographs of examples of embodiments of the present invention having different thicknesses and patterns of oxidized metal layers on a graphitic substrate. FIG. 3A is a digital photograph of a graphitic substrate that has been deposited with a metal layer (e.g., aluminum) that has been oxidized with a relatively thin oxide layer (e.g., approximately 7 microns). FIG. 3B shows a digital photograph of a graphitic substrate with a metal layer that has been oxidized with a relatively medium thickness (e.g., approximately 1.5 microns). FIG. 3C shows a digital photograph of a graphitic substrate where substantially the entire metal layer has been oxidized (e.g., approximately 25 microns thickness). FIG. 3D shows a digital photograph of a substrate that has been oxidized with a pattern, such as by utilizing a masking method, such as previously described with respect to steps 103 and 104 in FIG. 1. In this example, the oxidized region has a relatively thin thickness (e.g., approximately 7 microns), though any thickness of the oxide layer may be created using such a patterning method.

Printable copper nano-inks have been developed, as described in U.S. Published Patent Application Nos. 2008/0286488 and 2009/0311440, which are hereby incorporated by reference herein. As described in the published patent applications, photosintering involves a sintering of metal particles to fuse them to each other and a photoreduction process that reduces or eliminates an oxide layer on the metal particles to enhance the fusion, wherein the photoreduction includes an absorption of light by the particles at certain wavelengths to reduce the metal oxide to elemental metal. This simultaneous removal of the oxide coating and sintering of the resulting oxide-free metal nanoparticles creates highly conducting metallic conductors that have a lower resistivity than is obtainable by other metal nanoparticle ink or paste sintering methods. Photoreduction uses light energy rather than thermal (heat) energy. Such copper inks can he printed on low cost plastic substrates (e.g., polyimide for multi-layer flexible PCB and printed electronics). Copper ink formulations provide excellent dispersion of copper nanoparticles, and copper inks may be applied by inkjet printer or roll-to-roll printing on various substrates. The solvents and dispersants in copper nano-inks can be removed during sintering, such as, but not limited to, photosintering, leaving only copper in the copper films with good electrical conductivity.

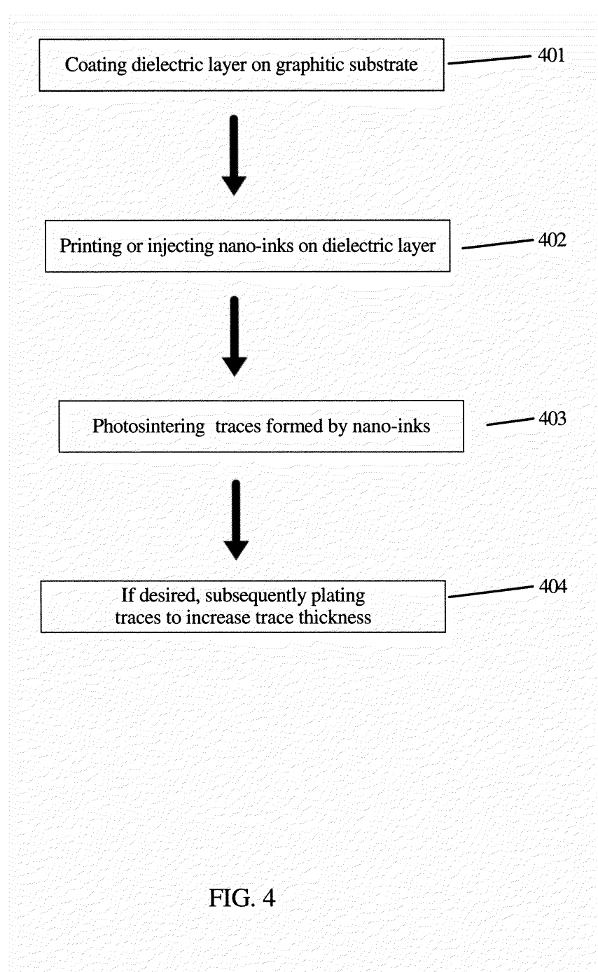

Referring to FIG. 4, the following describes a fabrication process of copper circuits on a polyimide-coated graphitic substrate. In step 401, a polyimide dielectric layer is coated on a graphite (graphitic) substrate, wherein the polyimide layer may be achieved by lamination of a polyimide film on a graphite surface, or by printing or spin coating a polyimide solution on the graphite. In step 402, copper nano-inks are printed or injected on the laminated polyimide or baked polyimide solution layer. In step 403, photosintering and/or thermal sintering of the copper nano-inks is performed to form a conductive circuit. In step 404, optionally, if desired, the copper layer thickness may be furthered increased using a subsequent electroplating method (e.g., also using a masking deposition process).

The dielectric layers on graphitic substrates may be polyimide-based materials. Other materials such as epoxy, PET, or poly phenyl-propyl silsesquioxane (PPSQ), may he optionally utilized. Ceramic filler particles, such as AlN, BN, or Al₂O₃ particles, or their mixture, may be added into the dielectric layer to enhance its thermal conductivity. The filler particle size may range from 2 nm to 100 μm.

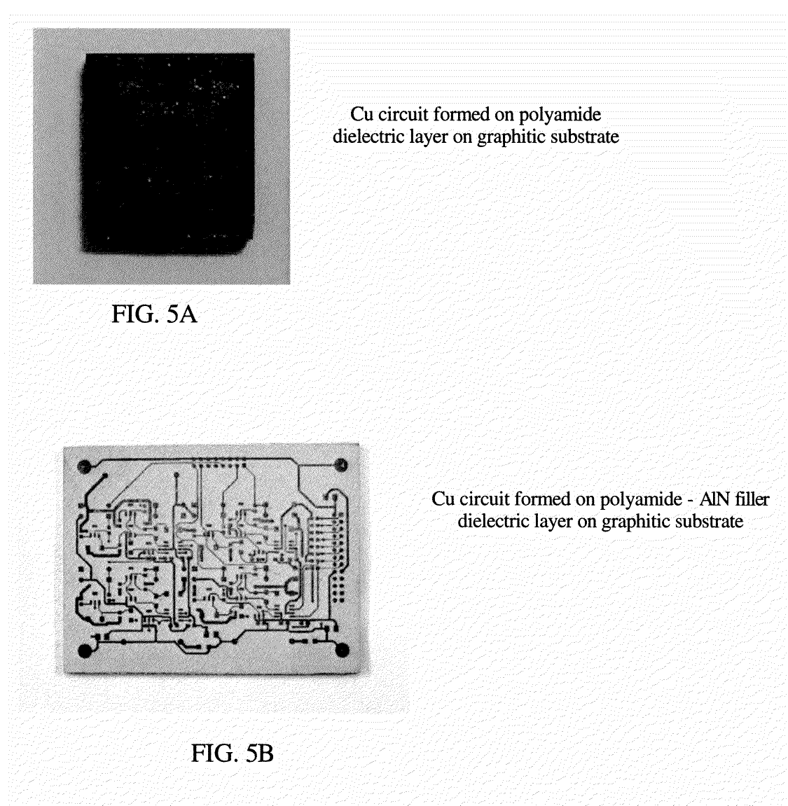

FIG. 5 shows examples of conductive circuits on dielectric graphitic substrates obtained by photosintering of copper nano-inks as described herein. FIG. 5A shows a digital photograph of conductive circuitry (e.g., copper) formed on a polyimide dielectric layer deposited on a graphitic substrate. FIG. 5B shows a digital photograph of conductive circuitry (e.g., copper) formed on a dielectric layer with a polyimide-AlN filler deposited on a graphitic substrate.

In embodiments described herein, the substrate material is not limited to graphite; the substrate may be another metal, such as copper, aluminum, and/or their alloys, or nonmetallic materials, such as SiC, glass, or Al₂O₃. In embodiments described herein, copper inks used to form the copper circuitry are not limited to copper nano-ink. Copper micro-ink may be optionally used where the metal particles in the ink are generally micron sized.

Embodiments described herein provide a material, such as but not limited to graphite, with a thin dielectric layer on it, wherein the thin layer may be a metal oxide layer that may be entirety or partially oxidized, or a polymeric layer on which is provided a printable conductive (e.g., copper) circuit.

Furthermore, since the surface dielectric layer is much thinner than the graphitic substrate and closely bonded to the substrate, the high thermal conductivity of the graphitic substrate ensures this material possesses superior thermal properties over conventional low CTE composites. An ability to utilize processes that form patterns of layers (such as, but not limited to, masking processes) enables embodiments of the present invention to produce such patterned features of the dielectric layer and/or conductive circuitry, which provides for embodiments of the present invention to be directly used to produce application-specific printed circuit boards.

What is claimed is:

1. A composite comprising:
a substrate with a high thermal conductivity:
a dielectric layer on the graphitic substrate; and
an electrical circuit on the dielectric layer.

2. The composite as recited in claim 1, wherein the substrate is a graphitic substrate.

3. The composite as recited in claim 1, wherein the dielectric layer is anodized aluminum.

4. The composite as recited in claim 1, wherein the dielectric layer is a polymeric material.

5. The composite as recited in claim 4, wherein the polymeric material is polyimide.

6. The composite as recited in claim 1, wherein the dielectric layer is a metal oxide.

7. The composite as recited in claim 1, wherein the dielectric layer is a ceramic material.

8. The composite as recited in claim 1, wherein the high thermal conductivity is approximately 250 W/m−K-450 W/m−K.

9. The composite as recited in claim 6, wherein the electrical circuit is conductive traces that are a photosintered copper ink formulation.

10. The composite as recited in claim 1, wherein the electrical circuit is conductive traces that arc a thermal sintered copper ink formulation.

11. A method comprising:
depositing a dielectric layer on a graphitic substrate; and
depositing an electrical circuit on the dielectric layer,

12. The method as recited in claim 11, wherein the depositing of the dielectric layer comprises depositing a metal material on the graphitic substrate and then oxidizing the metal material.

13. The method as recited in claim 12, wherein the oxidizing of the metal material comprises anodizing aluminum.

14. The method as recited in claim 11, wherein the depositing of the dielectric layer comprises depositing the metal material on the graphitic substrate, positioning a mask layer over the dielectric layer, wherein the mask layer has a predefined pattern, and then oxidizing the metal material through the mask layer to thereby oxidize the metal material in accordance with the predefined pattern.

15. The method as recited in claim 11, wherein the depositing of the dielectric layer on the graphitic substrate further comprises coating a polymeric material as the dielectric layer on the graphitic substrate.

16. The method as recited in claim 11, wherein the depositing of the dielectric layer on the graphitic substrate further comprises coating a ceramic material as the dielectric layer on the graphitic substrate.

17. The method as recited in claim 11, further comprising depositing a conductive ink on the dielectric layer, and then photosintering the conductive ink to form conductive circuitry.

18. The method as recited in claim 11, further comprising depositing a conductive ink on the dielectric layer, and then thermally sintering the conductive ink to form conductive circuitry.
